(19) United States
(12) Patent Application Publication
(10) Pub. No.: US 2025/0351652 A1
(43) Pub. Date: Nov. 13, 2025

(54) DISPLAY DEVICE AND METHOD FOR MANUFACTURING DISPLAY DEVICE

(71) Applicant: Samsung Display Co., LTD., Yongin-si (KR)

(72) Inventors: Ki Bum KIM, Yongin-si (KR); Tae Gyun KIM, Yongin-si (KR); So Young LEE, Yongin-si (KR)

(73) Assignee: Samsung Display Co., LTD., Yongin-si (KR)

(21) Appl. No.: 19/187,040

(22) Filed: Apr. 23, 2025

(30) Foreign Application Priority Data
May 7, 2024 (KR) 10-2024-0059650

(51) Int. Cl. H10H 29/855; H01L 25/075; H10H 29/01; H10H 29/03; H10H 29/49; H10H 29/80; H10H 29/856

(52) U.S. Cl. CPC H10H 29/855; H01L 25/0753; H10H 29/012; H10H 29/03; H10H 29/032; H10H 29/0363; H10H 29/0364; H10H 29/49; H10H 29/8323; H10H 29/856

(57) ABSTRACT

A display device includes a substrate including a display area and a non-display area, a plurality of pixel electrodes disposed on the substrate in the display area, light emitting elements each disposed on a corresponding one of the plurality of pixel electrodes, a common electrode disposed on the light emitting elements and commonly connected to a plurality of pixels, and an auxiliary electrode disposed on the common electrode and not overlapping with the light emitting elements in a thickness direction of the substrate.

### CROSS-REFERENCE TO RELATED APPLICATION(S)

This application claims priority to and benefits of Korean Patent Application No. 10-2024-0059650 under 35 U.S.C. 119, filed on May 7, 2024, in the Korean Intellectual Property Office (KIPO), the entire contents of which are incorporated herein by reference.

### BACKGROUND

### 1. Technical Field

The disclosure relates to a display device and a method for manufacturing the same.

### 2. Description of the Related Art

The importance of display devices is increasing with the development of multimedia. In response to this, various types of display devices such as organic light emitting displays (OLED), liquid crystal displays (LCD), etc. are being used.

As a device for displaying an image of a display device, the display device includes a display panel such as a light emitting display panel or a liquid crystal display panel. Among them, the light emitting display panel may include a light emitting diode (LED), such as an organic light emitting diode that utilizes an organic substance as a fluorescent material, or an inorganic light emitting diode that utilizes an inorganic substance as a fluorescent material.

A display panel using an inorganic light emitting diode as a light emitting diode may include multiple pixels and a common electrode, which is a common layer commonly connected to the pixels. The common electrode has a high possibility of IR drop as the amount of current increases. For example, the possibility of a decrease in luminance at the center of the panel may increase. The larger the display panel area, the more luminance unevenness occurs.

Aspects and features of embodiments of the disclosure are to provide a display device and a manufacturing method of the display device that minimize luminance unevenness by using an auxiliary electrode with low specific resistance to reduce the IR drop of the common electrode.

However, aspects of the disclosure are not restricted to the one set forth herein. The above and other aspects of the disclosure will become more apparent to one of ordinary skill in the art to which the disclosure pertains by referencing the detailed description of the disclosure given below.

### SUMMARY

According to an embodiment, a display device may include a substrate including a display area and a non-display area, a plurality of pixel electrodes disposed on the substrate in the display area, light emitting elements each disposed on a corresponding one of the plurality of pixel electrodes, a common electrode disposed on the light emitting elements and commonly connected to a plurality of pixels, and an auxiliary electrode disposed on the common electrode and not overlapping the light emitting elements in a thickness direction of the substrate.

The auxiliary electrode may be made of a material having a resistance lower than a resistance of the common electrode.

The auxiliary electrode may have a thickness smaller than a thickness of the common electrode.

The display device may further include a micro lens overlapping the light emitting elements in the thickness direction.

The auxiliary electrode may not overlap the micro lens in the thickness direction.

The auxiliary electrode may be electrically connected to the common electrode.

The non-display area may include a common voltage supply area, the display device may further include a first common connection electrode disposed on the substrate in the common voltage supply area, the common electrode may extend from the display area to the common voltage supply area, the auxiliary electrode may include a first auxiliary electrode disposed in the display area and a second auxiliary electrode disposed in the common voltage supply area, and the second auxiliary electrode may be electrically connected to the first common connection electrode by penetrating the common electrode.

The second auxiliary electrode may be in contact with the common electrode and electrically connect the first common connection electrode and the common electrode.

The display device may further include a bonding electrode disposed between the plurality of pixel electrodes and the light emitting elements, and a second common connection electrode disposed on the first common connection electrode. The second common connection electrode and the bonding electrode may be disposed on a same layer, and the second auxiliary electrode may be in contact with the second common connection electrode.

The non-display area may further include a pad area, the display device may further include a pad electrode and a dummy electrode disposed in the pad area, the dummy electrode overlapping the first pad electrode in the thickness direction, and as the dummy electrode and the common electrode may be disposed on a same layer.

The auxiliary electrode may further include a third auxiliary electrode disposed on the dummy electrode, and the display device may further include a transparent conductive layer disposed on the third auxiliary electrode.

The third auxiliary electrode may be made of a material having a resistance lower than a resistance of the dummy electrode.

The third auxiliary electrode may be in contact with the transparent conductive layer and the dummy electrode, and electrically connect the transparent conductive layer and the dummy electrode.

The transparent conductive layer may include at least one of indium tin oxide (ITO), indium zinc oxide (IZO), and other transparent conductive material.

The display device may further include a bonding electrode disposed between the plurality of pixel electrodes and the light emitting elements, and a second common connection electrode disposed on the first common connection electrode. The second common connection electrode and the bonding electrode may be disposed on a same layer, and the second auxiliary electrode may be in contact with the second common connection electrode.

The display device may further include an insulating layer surrounding a side of the light emitting elements, and a reflective layer surrounding the side of the light emitting elements on the insulating layer.

According to an embodiment, a method of manufacturing a display device may include transferring a plurality of light emitting elements to a substrate including a pixel electrode in a display area and a common connection electrode in a non-display area, forming a first insulating layer and a reflective layer surrounding side surfaces of the plurality of light emitting elements, forming an organic layer surrounding the plurality of light emitting elements and having a planar surface above the plurality of light emitting elements, forming a common electrode on the plurality of light emitting elements and the organic layer, and forming an auxiliary electrode on the common electrode not overlapping the plurality of light emitting elements in a thickness direction of the substrate.

After the forming of the auxiliary electrode, the auxiliary electrode may be electrically connected to the common connection electrode by penetrating the organic layer in the non-display area.

The substrate may further include a pad electrode in the non-display area, and the forming of the common electrode on the plurality of light emitting elements and the organic layer may include forming an electrode material layer on the plurality of light emitting elements and the organic layer, and forming a dummy electrode that overlaps the pad electrode in the thickness direction and the common electrode that overlaps the common connection electrode in the thickness direction by short-circuiting a portion of the electrode material layer that overlaps the pad electrode in the thickness direction and another portion of the electrode material layer that overlaps the common connection electrode in the thickness direction by an etching process.

The method may further include forming a transparent conductive layer on the auxiliary electrode overlapping the dummy electrode in the thickness direction.

The method may further include forming a lens-shaped optical structure on a light emitting element layer including the plurality of light emitting elements and the common electrode. The auxiliary electrode may not overlap the lens-shaped optical structure in the thickness direction.

According to an embodiment, an electronic device may include a display module that provides an image, and a processor that transmits an image data signal to the display module. The display module may include a substrate including a display area and a non-display area, a plurality of pixel electrodes disposed on the substrate in the display area, light emitting elements each disposed on a corresponding one of the plurality of pixel electrodes, a common electrode disposed on the light emitting elements and commonly connected to a plurality of pixels, and an auxiliary electrode disposed on the common electrode and not overlapping the light emitting elements in a thickness direction of the substrate.

According to the display device and the manufacturing method of the display device according to the embodiments, an IR drop of the common electrode may be reduced and the luminance unevenness phenomenon may be minimized.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to one embodiment.

FIG. 2 is a plan view illustrating one embodiment of area A of FIG. 1.

FIG. 3 is a schematic cross-sectional view illustrating one embodiment of a cross-section of a display panel corresponding to line I-I′ in FIG. 2.

FIG. 4 is a schematic cross-sectional view illustrating another embodiment of a cross-section of a display panel corresponding to line I-I′ in FIG. 2.

FIG. 5 is a plan view illustrating an auxiliary electrode according to one embodiment.

FIG. 6 is a plan view illustrating a transparent conductive layer according to one embodiment.

FIG. 7 is a schematic cross-sectional view illustrating a light emitting element LE according to one embodiment.

FIG. 8 is a schematic cross-sectional view illustrating a light emitting element LE according to one embodiment.

FIG. 9 is a schematic cross-sectional view illustrating a light emitting element LE according to one embodiment.

FIG. 10 is a flowchart describing a manufacturing method of a display device 10 according to one embodiment.

FIGS. 11 to 21 are schematic cross-sectional views illustrating a manufacturing method of a display panel 100 according to one embodiment.

FIG. 22 is a block diagram of an electronic device according to one embodiment of the present disclosure.

FIG. 23 is a schematic diagram of an electronic device according to various embodiments of the present disclosure.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, specific embodiments will be described with reference to the accompanying drawings.

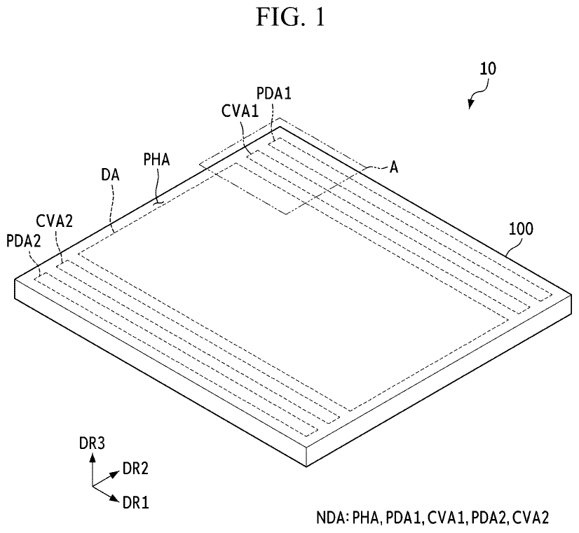

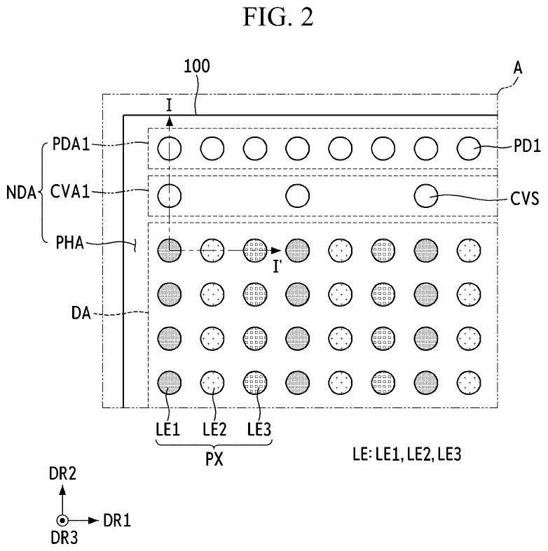

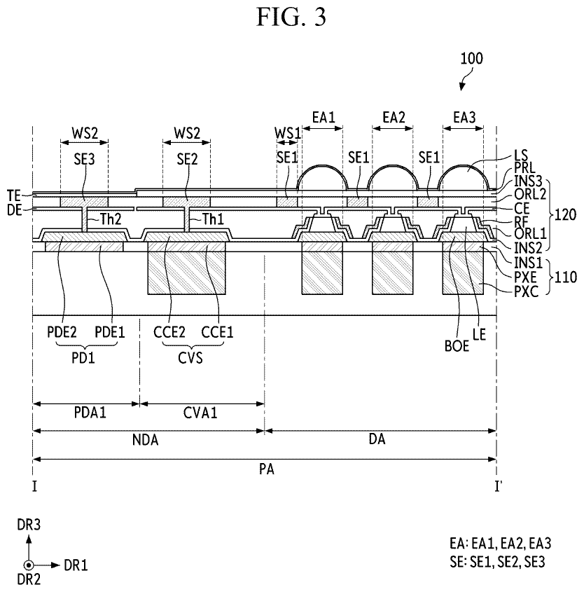

FIG. 1 is a perspective view illustrating a display device according to one embodiment. FIG. 2 is a plan view illustrating one embodiment of area A of FIG. 1. FIG. 3 is a schematic cross-sectional view illustrating one embodiment of a cross-section of a display panel corresponding to line I-I′in FIG. 2.

FIGS. 1 to 3 schematically illustrate an embodiment in which the display device 10 is an LEDoS (Light Emitting Diode on Silicon) in which light emitting diodes are disposed as light emitting elements LE on a semiconductor circuit board formed by a semiconductor process using a silicon wafer (e.g., a backplane substrate 110 of the display panel 100 on which a pixel circuit PXC or the like is formed based on a silicon wafer). However, devices including light emitting elements LE are not limited thereto. For example, the light emitting elements LE manufactured according to embodiments may be applied to display devices of different types and/or structures or may be applied to devices of different types and/or structures, such as lighting devices, etc.

In FIGS. 1 to 3, the first direction DR1 may indicate a horizontal direction of the display panel 100, and the second direction DR2 may indicate a vertical direction of the display panel 100. The third direction DR3 may indicate a thickness direction of the display panel 100.

First, referring to FIGS. 1 and 2, the display device 10 according to one embodiment may include a display panel 100 including a display area DA and a non-display area NDA.

The display panel 100 may have a rectangular planar shape with a long side in the first direction DR1 and a short side in the second direction DR2 in a plan view. However, the planar shape of the display panel 100 is not limited thereto, and the display panel 100 may have other shape. For example, the display panel 100 may have a polygonal, circular, elliptical, or other non-rectangular planar shape other than a rectangular shape.

The display area DA may be an area where an image is displayed, and the non-display area NDA may be an area where the image is not displayed. In one embodiment, the planar shape of the display area DA may follow the planar shape of the display panel 100. In FIG. 1, the planar shape of the display area DA is illustrated as a rectangle. The display area DA may be disposed in the central area of the display panel 100. The non-display area NDA may be disposed adjacent to the display area DA. For example, the non-display area NDA may surround the display area DA.

The display area DA may include multiple pixels PX. Each pixel PX may include at least two light emitting elements LE.

In one embodiment, each pixel PX may include three light emitting elements LE. For example, each pixel PX may include a first light emitting element LE1, a second light emitting element LE2, and a light emitting element LE3. The number and/or type of light emitting elements LE provided to the pixels PX may be varied in different embodiments.

In one embodiment, each pixel PX may include light emitting elements LE that emit light of different colors. For example, the first light emitting element LE1, the second light emitting element LE2, and the light emitting element LE3 may emit light of different colors.

The first light emitting element LE1 may emit a first light. The first light may be red light. For example, a main peak wavelength (R-peak) of the first light may be in a range of about 600 nm to about 750 nm, but the disclosure is not limited thereto.

The second light emitting element LE2 may emit a second light. The second light may be green light. For example, a main peak wavelength (G-peak) of the second light may be in a range of about 480 nm to about 560 nm, but the disclosure is not limited thereto.

The third light emitting element LE3 may emit a third light. The third light may be blue light. For example, a main peak wavelength (B-peak) of the third light may be in a range of about 370 nm to about 460 nm, but the disclosure is not limited thereto.

In another embodiment, the first light emitting element LE1, the second light emitting element LE2, and the light emitting element LE3 may emit light of a same color. A light conversion layer including a light conversion element (e.g., a quantum dot) for converting the color of light (or a wavelength band corresponding thereto) emitted from the at least one light emitting element LE into light of another color (or a wavelength band corresponding thereto) may be disposed on at least one light emitting element LE among the first light emitting element LE1, the second light emitting element LE2, and the light emitting element LE3.

In one embodiment, the first light emitting element LE1, the second light emitting element LE2, and the light emitting element LE3 of each pixel PX may be sequentially disposed in the first direction DR1. In one embodiment, the first light emitting elements LE1 may be arranged in the second direction DR2. The second light emitting elements LE2 may be arranged in the second direction DR2. The third light emitting elements LE3 may be arranged in the second direction DR2. For example, in each pixel column extending in the second direction DR2, the first light emitting element LE1, the second light emitting element LE2, or the third light emitting element LE3 may be arranged. However, the disclosure is not limited thereto, and the pixels PX, and the arrangement structure of the light emitting elements LE provided in the pixels PX, may be varied in different embodiments.

In one embodiment, the light emitting elements LE may be arranged in the display area DA at substantially equal intervals but the disclosure is not limited thereto. For example, the positions and/or array spacing of the light emitting elements LE may be varied depending on the embodiments.

In one embodiment, the sizes (e.g., areas in a plan view) of the light emitting elements LE may be substantially the same as each other. For example, the first light emitting element LE1, the second light emitting element LE2, and the light emitting element LE3 may have substantially the same size. However, the disclosure is not limited thereto, and the size of each light emitting element LE and/or the area of the light emitting areas corresponding to the light emitting elements LE may be varied in different embodiments.

In one embodiment, the light emitting elements LE may have a circular planar shape in a plan view, but the disclosure is not limited thereto. For example, the light emitting elements LE may have a rectangular shape, another polygonal shape, an elliptical shape, or an irregular shape. For example, the light emitting elements LE may have substantially a same planar shape as each other or may have different planar shapes for each group.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connecting portions CVS connected to a common electrode (e.g., common electrode CE in FIG. 3). For example, the common electrode may extend from the display area DA to the first common voltage supply area CVA1 and the second common voltage supply area CVA2 and may be electrically connected to the common electrode connecting portions CVS. A common voltage may be supplied to the common electrode through common electrode connecting portions CVS.

The common electrode connecting portions CVS may be disposed in a common voltage supply area (e.g., the first common voltage supply area CVA1 and/or the second common voltage supply area CVA2) of the non-display area NDA. The common electrode connecting portions CVS may include a conductive material (e.g., a metal material such as aluminum (Al)). Although FIGS. 1 and 2 illustrate that the common electrode connecting portions CVS are disposed in the non-display area NDA, the disclosure is not limited thereto. For example, the common electrode connecting portions CVS may be disposed in the display area DA. For example, the common electrode connecting portions CVS may be disposed in pixel areas or between pixel areas.

The common electrode connecting portions CVS of the first common voltage supply area CVA1 may be electrically connected to one of the first pads PD1 of the first pad area PDA1. For example, the common electrode connecting portions CVS of the first common voltage supply area CVA1 may be supplied with a common voltage from one of the first pads PD1 of the first pad area PDA1.

The first pads PD1 may be disposed in the first pad area PDA1. The first pads PD1 may be electrically connected to a circuit board (not illustrated) through a conductive connection member. For example, the first pads PD1 may be electrically connected to a circuit pad provided on a circuit board through wires.

The common electrode connecting portions CVS of the second common voltage supply area CVA2 may be electrically connected to one of the second pads of the second pad area PDA2. For example, the common electrode connecting portions CVS of the second common voltage supply area CVA2 may be supplied with a common voltage from one of the second pads of the second pad area PDA2. In another embodiment, the display panel 100 may not include the second common voltage supply area CVA2.

The first pad area PDA1 may be disposed on a side (e.g., the upper side) of the display panel 100. The first pad area PDA1 may include first pads PD1 connected to an external circuit board.

The second pad area PDA2 may be disposed on another side (e.g., the lower side) of the display panel 100. The second pad area PDA2 may include second pads connected to an external circuit board. In another embodiment, the display panel 100 may not include the second pad area PDA2.

The second pads may be disposed in the second pad area PDA2 of the non-display area NDA. The second pads may be connected to the circuit board through a conductive connection member. For example, the second pads may be electrically connected to circuit pads provided on the circuit board through wires.

The peripheral area PHA may be a part of the non-display area NDA excluding the first common voltage supply area CVA1, the second common voltage supply area CVA2, the first pad area PDA1, and the second pad area PDA2. The peripheral area PHA may surround the display area DA, as well as the first common voltage supply area CVA1, the second common voltage supply area CVA2, the first pad area PDA1, and the second pad area PDA2 in a plan view.

Referring to FIG. 3, the display panel 100 may include a display area DA and a non-display area NDA.

The display panel 100 may include a backplane substrate 110 and a light emitting element layer 120. In one embodiment, the display panel 100 may further include an optical structure (or light emitting structure) provided on the light emitting element layer 120, for example, a lens-type optical structure LS.

The display panel 100 may further include additional components according to embodiments. For example, the display panel 100 may further include a light conversion layer for converting the color and/or wavelength of light emitted from at least some of the light emitting elements LE, and/or a color filter layer for controlling light of a color emitted from each of the light emitting area EA.

The display panel 100 may include light emitting areas EA located in the display area DA. Each of the light emitting areas EA may include at least one light emitting element LE. For example, the light emitting areas EA may include a first light emitting area EA1 provided with at least one first light emitting element LE1, a second light emitting area EA2 provided with at least one second light emitting element LE2, and a third light emitting area EA3 provided with at least one third light emitting element LE3. In one embodiment, first light, second light, and third light may be emitted from the first light emitting area EA1, the second light emitting area EA2, and the third light emitting area EA3, respectively.

The backplane substrate 110 may include a display area DA including light emitting areas EA. In one embodiment, the backplane substrate 110 may be a semiconductor circuit board formed through a semiconductor process using a silicon wafer. For example, a silicon wafer may be used as a base member to form the display panel 100.

The backplane substrate 110 may include pixel circuits PXC and pixel electrodes PXE provided in the display area DA. For example, each light emitting area EA of the display panel 100 may be provided with at least one light emitting element LE, and the backplane substrate 110 may include pixel circuits PXC and pixel electrodes PXE connected (e.g., electrically connected) to each of the light emitting elements LE disposed in the respective light emitting areas EA.

In one embodiment, the backplane substrate 110 may further include a first insulating layer INS1 disposed around the pixel electrodes PXE.

The pixel circuits PXC may be provided in the display area DA corresponding to the area where each pixel PX and/or the light emitting areas EA are formed. In one embodiment, each of the pixel circuits PXC may include a complementary metal-oxide semiconductor (CMOS) circuit formed using a semiconductor process.

Each of the pixel circuits PXC may include at least one transistor formed through a semiconductor process. Each of the pixel circuits PXC may further include at least one capacitor formed through a semiconductor process.

The pixel circuits PXC may be electrically connected to a corresponding pixel electrode PXE. For example, the pixel circuits PXC and the pixel electrodes PXE may be connected in a one-to-one correspondence. Each of the pixel circuits PXC may apply a pixel voltage to the pixel electrode PXE connected to the pixel circuit PXC.

The pixel electrodes PXE may be connected to a corresponding pixel circuit PXC. The pixel electrodes PXE may be individually provided in each light emitting area EA and may be electrically connected to the light emitting elements LE located in each light emitting area EA. Accordingly, the light emitting elements LE disposed in each light emitting area EA may be individually and/or independently controlled.

Each of the pixel electrodes PXE may be disposed on the corresponding pixel circuit PXC. In one embodiment, each of the pixel electrodes PXE may be formed integrally with the pixel circuit PXC and may be an electrode exposed from the pixel circuit PXC. For example, each of the pixel electrodes PXE may protrude from a top surface of the pixel circuit PXC. Each of the pixel electrodes PXE may receive a pixel voltage from the pixel circuit PXC. The pixel electrodes PXE may include a conductive material (e.g., a metal material such as aluminum (Al)).

In one embodiment, the first insulating layer INS1 may be disposed around the pixel electrodes PXE. The first insulating layer INS1 may be provided on the semiconductor circuit board on which the pixel circuits PXC are formed. In one embodiment, the first insulating layer INS1 may be disposed between the pixel electrodes PXE to surround the pixel electrodes PXE.

The first insulating layer INS1 may expose at least a portion of each of the pixel electrodes PXE. For example, the first insulating layer INS1 may include openings corresponding to the pixel electrodes PXE and may expose the top surface of the pixel electrodes PXE. The first insulating layer INS1 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or other insulating material.

The non-display area NDA may further include a common voltage supply area CVA1 and a first pad area PDA1.

In one embodiment, the backplane substrate 110 may include a common electrode connecting portion CVS located in the common voltage supply area CVA1 and a first pad PD1 located in the first pad area PDA1.

In one embodiment, the common electrode connecting portion CVS may include a first common connection electrode CCE1 and a second common connection electrode CCE2.

The first common connection electrode CCE1 and the pixel electrode PXE may be formed through a same process. Accordingly, the first common connection electrode CCE1 and the pixel electrodes PXE may include a same material, and have a same thickness in the third direction DR3.

The second common connection electrode CCE2 may be disposed on the first common connection electrode CCE1. The second common connection electrode CCE2 and the bonding electrodes BOE may be formed through a same process. Accordingly, the second common connection electrode CCE2 and the bonding electrodes BOE may include a same material, and have a same thickness in the third direction DR3.

In one embodiment, each of the first pads PD1 may be connected to the circuit board through a corresponding conductive connection member, such as a wire. The circuit board may be a flexible printed circuit board (FPCB), a printed circuit board (PCB), a flexible printed circuit (FPC), or a flexible film, such as a chip on film (COF).

In one embodiment, the first pad PD1 may include a first pad electrode PDE1 and a second pad electrode PDE2.

The first pad electrode PDE1 and the first common connection electrode CCE1 may be formed through a same process. Accordingly, the first pad electrode PDE1 and the first common connection electrode CCE1 may include a same material, and have a same thickness in the third direction DR3.

The second pad electrode PDE2 may be disposed on the first pad electrode PDE1. The second pad electrode PDE2 may be formed through a same process as the second common connection electrode CCE2 and the bonding electrodes BOE. Accordingly, the second pad electrode PDE2 and the second common connection electrode CCE2 may include a same material, and have a same thickness in the third direction DR3.

The light emitting element layer 120 may include bonding electrodes BOE, light emitting elements LE, and a common electrode CE. In one embodiment, the light emitting element layer 120 may further include organic layers ORL1, ORL2 disposed around the light emitting elements LE, and/or a third insulating layer INS3 disposed on the common electrode CE.

The light emitting element layer 120 may include bonding electrodes BOE, light emitting elements LE, a common electrode CE, and an auxiliary electrode SE in the display area DA. In one embodiment, the light emitting element layer 120 may further include a first organic layer ORL1 disposed around the light emitting elements LE, a second organic layer ORL2 disposed between the auxiliary electrodes SE on the common electrode CE, and a second insulating layer INS2 disposed on the second organic layer ORL2.

In one embodiment, the light emitting element layer 120 may further include additional components. For example, the light emitting element layer 120 may further include a reflective layer RF and/or a light blocking layer provided between the light emitting elements LE and/or on the sides of the light emitting elements LE.

The bonding electrodes BOE may be provided at positions corresponding to each pixel electrode PXE and electrically connected to each pixel electrode PXE. For example, the bonding electrodes BOE may be disposed on each pixel electrode PXE.

The bonding electrodes BOE may include a first bonding electrode and a second bonding electrode. The second bonding electrode may be disposed on the first bonding electrode, and the first bonding electrode and the second bonding electrode may have sizes and shapes that correspond to each other.

The first bonding electrode and the second bonding electrode may include a conductive bonding material suitable for bonding or adhering the light emitting elements LE to the pixel electrodes PXE. For example, each of the bonding electrodes BOE may be a single-layer or multi-layer electrode containing gold (Au), copper (Cu), aluminum (Al), tin (Sn), or another metal material (e.g., bonding metal).

The light emitting elements LE may be disposed on each bonding electrode BOE. The light emitting elements LE may be electrically connected between each pixel electrode PXE and the common electrode CE.

The light emitting elements LE may include semiconductor layers grown on a semiconductor substrate (e.g., a wafer substrate) by epitaxial growth. For example, the light emitting elements LE may include a first semiconductor layer doped with a first conductivity type, a second semiconductor layer doped with a second conductivity type, and an active layer interposed between the first and second semiconductor layers.

A detailed description of the structure and manufacturing method of the light emitting elements LE according to one embodiment will be described below.

The side surfaces of the light emitting elements LE, excluding one side of the light emitting elements LE, may be surrounded by the second insulating layer INS2. Further, the second insulating layer INS2 may cover a portion of the top surface and a side surface of the bonding electrode BOE.

The first organic layer ORL1 may be provided around the light emitting elements LE. For example, the first organic layer ORL1 may be disposed between the light emitting areas EA to surround the light emitting areas EA provided with the light emitting elements LE, and may surround the light emitting elements LE and the bonding electrodes BOE. In one embodiment, the first organic layer ORL1 may be a filler that fills the gap between the light emitting elements LE. The first organic layer ORL1 may expose a portion of the light emitting elements LE, for example, a top surface.

The first organic layer ORL1 may also be disposed in the non-display area NDA. In the non-display area NDA, the first organic layer ORL1 may cover the second common connection electrode CCE2 and the second pad electrode PDE2.

The first organic layer ORL1 may include an insulating material. For example, the first organic layer ORL1 may be a single layer or multiple layers of organic insulating film including an acrylic resin, an epoxy resin, a phenolic resin, a polyamide resin, a polyimide resin, or other organic insulating material.

The common electrode CE may be disposed on top of the light emitting elements LE that are not covered by the first organic layer ORL1. In one embodiment, the common electrode CE may be entirely disposed in the display area DA and cover the light emitting elements LE and the first organic layer ORL1. The common electrode CE may be a common layer commonly formed and/or connected to the light emitting elements LE of the display area DA and the pixels PX including the same. The common electrode CE may extend to the common voltage supply area CVA1.

The common electrode CE may include a transparent conductive material capable of transmitting light. For example, the common electrode CE may include indium tin oxide (ITO), indium zinc oxide (IZO), or other transparent conductive material. In one embodiment, the common electrode CE may function as a cathode electrode (or anode electrode) of the light emitting elements LE.

A dummy electrode DE may be disposed on the first organic layer ORL1 in the first pad area PDA1. The dummy electrode DE and the common electrode CE may be electrically insulated with each other, but may be formed through a same process. Accordingly, the dummy electrode DE and the common electrode CE may include a same material, and have a same thickness in the third direction DR3.

The auxiliary electrode SE may be disposed on the common electrode CE and the dummy electrode DE. The auxiliary electrode SE may function to prevent the voltage drop of the electrode connected to the bottom. For example, the auxiliary electrode SE may prevent a voltage drop of the common electrode CE.

The auxiliary electrode SE may include a material having a resistivity lower than the common electrode CE. For example, the auxiliary electrode SE may include at least one of copper (Cu), chromium (Cr), a chromium alloy, molybdenum (Mo), a molybdenum alloy, and an oxide thereof (CrOₓ, MoOₓ).

The auxiliary electrode SE disposed on the display area DA may be a first auxiliary electrode SE1, the auxiliary electrode SE disposed on the first common voltage supply area CVA1 may be a second auxiliary electrode SE2, and the auxiliary electrode SE disposed on the first pad area PDA1 may be a third auxiliary electrode SE3.

The first auxiliary electrode SE1 may be formed in a mesh type in a plan view and electrically connected to the common electrode CE. For example, the first auxiliary electrode SE1 may overlap the non-emitting area and may not overlap the light emitting area in a plan view.

As used herein, “in a plan view” may be set based on a plane defined by the first direction DR1 and the second direction DR2. As used herein, “in cross section” may be defined as viewed in the first direction DR1 or the second direction DR2.

The second auxiliary electrode SE2 may be electrically connected to the first auxiliary electrode SE1 and connected to the common electrode connecting portion CVS through a hole Th1 penetrating the common electrode CE, the first organic layer ORL1, and the second insulating layer INS2, which are members formed below.

In one embodiment, the second auxiliary electrode SE2 may have the same or larger area than the first auxiliary electrode SE1 in a plan view. The second auxiliary electrode SE2 may have a width WS2 that is wider than the width WS1 of the first auxiliary electrode SE1 in a horizontal direction.

The third auxiliary electrode SE3 may be electrically insulated from the first auxiliary electrode SE1 and the second auxiliary electrode SE2 and may be connected to the first pad PD1 through a hole Th2 penetrating the dummy electrode DE, the first organic layer ORL1 and the second insulating layer INS2, which are members formed on the bottom.

The third auxiliary electrode SE3 may have a width WS2 that is the same as the width WS2 of the second auxiliary electrode SE2. The third auxiliary electrode SE3 may have an area equal to or larger than an area of the first auxiliary electrode SE1 in a plan view. The third auxiliary electrode SE3 may have a width WS2 that is wider than the width WS1 of the first auxiliary electrode SE1 in a horizontal direction.

The common electrode CE may be electrically connected to the common electrode connecting portions CVS and the second auxiliary electrode SE2 disposed in the first common voltage supply area CVA1 and/or the second common voltage supply area CVA2. Accordingly, the common electrode CE may be supplied with a common voltage through the common electrode connecting portions CVS.

The third auxiliary electrode SE3 may be disposed in the first pad area PDA1.

A second organic layer ORL2 may be provided between the first auxiliary electrode SE1, the second auxiliary electrode SE2, and the third auxiliary electrode SE3. For example, the second organic layer ORL2 may be disposed in the display area DA and the non-display area NDA and surround the auxiliary electrode SE. In one embodiment, the second organic layer ORL2 may be a filler that fills the gap between the first auxiliary electrode SE1, the second auxiliary electrode SE2, and the third auxiliary electrode SE3. The second organic layer ORL2 may expose a portion of the auxiliary electrode SE, for example, the top surface.

A third insulating layer INS3 may be disposed on the first auxiliary electrode SE1 and the second auxiliary electrode SE2. The third insulating layer INS3 may cover the entire surface of the display area DA and the first common voltage supply area CVA1.

A transparent conductive layer TE may be disposed on the third auxiliary electrode SE3. The transparent conductive layer TE may be disposed in the entire area of the first pad area PDA1.

The transparent conductive layer TE may be disposed on the third auxiliary electrode SE3 in the first pad area PDA1 and may be in contact with the third auxiliary electrode SE3. The transparent conductive layer TE may include indium tin oxide (ITO), indium zinc oxide (IZO), or other transparent conductive material.

The third insulating layer INS3 may be disposed on the auxiliary electrode SE and the second organic layer ORL2 in the first common voltage supply area CVA1 and the display area DA. For example, the third insulating layer INS3 may be a capping layer entirely disposed in the display area DA and the first common voltage supply area CVA1 and cover the auxiliary electrode SE and the second organic layer ORL2. The third insulating layer INS3 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or the like, or any other insulating material.

In one embodiment, the display panel 100 may include a lens-type optical structure LS provided on the light emitting device layer 120. In one embodiment, the display panel 100 may further include a protective layer PRL covering the lens-type optical structure LS.

The lens-type optical structure LS may be disposed in each light emitting area EA and overlap the light emitting elements LE in a plan view. In one embodiment, the lens-type optical structure LS may be an optical structure in a form of a convex lens provided on top of the light emitting elements LE, but the type and/or shape of the optical structure is not limited thereto. By disposing the lens-type optical structure LS on top of the light emitting elements LE, the light output characteristics of the pixels PX may be adjusted and/or improved.

The lens-type optical structure LS may be formed of a transparent material so that light incident from the light emitting elements LE may be transmitted. For example, the lens-type optical structure LS may be formed of glass, a plastic, a ceramic, or any other material, and may be formed of an optical material with a high refractive index.

The auxiliary electrode SE may not overlap the lens-type optical structure LS in a plan view.

The protective layer PRL may be disposed on the lens-type optical structure LS and cover the lens-type optical structure LS. The protective layer PRL may be formed of a transparent and durable material (e.g., plastic glass, organic glass, optical glass, ceramic, etc.), but the disclosure is not particularly limited thereto, as long as the material is suitable for protecting the lens-type optical structure LS. FIG. 3 schematically illustrates an embodiment in which the protective layer PRL has a bend that corresponds to the shape of the lens-type optical structure LS, but the disclosure is not limited thereto. For example, the protective layer PRL may be formed in a shape that may flatten the top surface of the display panel 100 on which the lens-type optical structure LS is formed.

The display device according to one embodiment may eliminate the risk of short-circuiting components below the common electrode, such as the side reflective layer of the light emitting element, by disposing the auxiliary electrode on the common electrode.

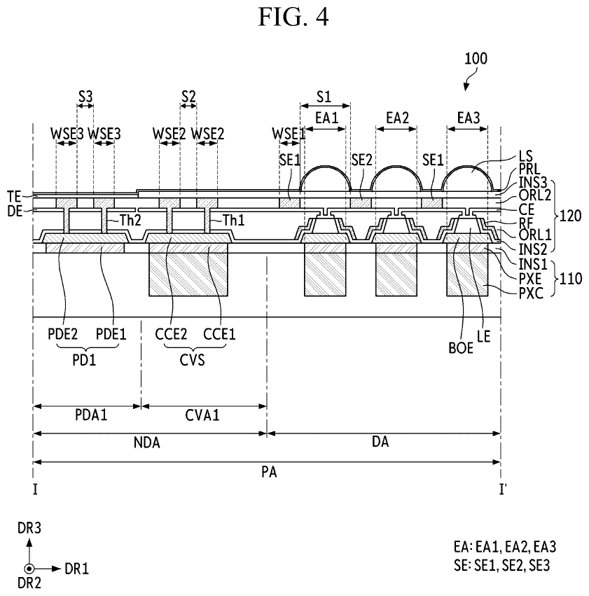

FIG. 4 is a schematic cross-sectional view illustrating another embodiment of a cross-section of a display panel corresponding to line I-I′ in FIG. 2.

FIG. 4 illustrates the shape and arrangement of the second auxiliary electrode SE2 and the third auxiliary electrode SE3 in the non-display area NDA different from the shape and arrangement of the second auxiliary electrode SE2 and the third auxiliary electrode SE3 as described with reference to FIG. 3. The embodiment described with reference to FIG. 4 may be same as the embodiment described above with reference to FIG. 3 except that the widths WSE2 and WSE3 of the second auxiliary electrode SE2 and the third auxiliary electrode SE3 are the same as the width WSE1 of the first auxiliary electrode SE1.

Multiple second auxiliary electrodes SE2 may be disposed in the common voltage supply area CVA1, the width WSE2 of each second auxiliary electrode SE and the width WSE1 of the first auxiliary electrode SE1 may be same, and the separation distance S2 between the second auxiliary electrodes SE2 may be less than the separation distance S1 between the first auxiliary electrodes SE1.

Multiple third auxiliary electrodes SE3 may be disposed in the first pad area PDA1, the width WSE3 of each of the third auxiliary electrodes SE3 and the width WSE1 of the first auxiliary electrode SE1 may be same, and the separation distance S3 between the third auxiliary electrodes SE3 may be less than the separation distance S1 between the first auxiliary electrodes SE1.

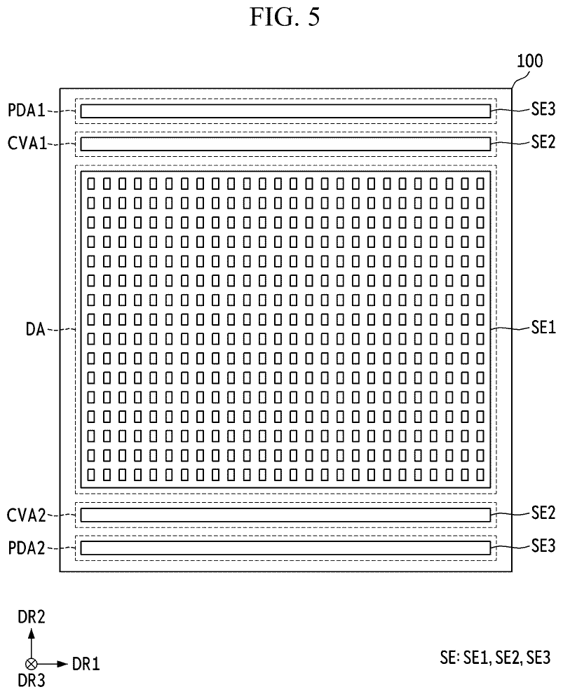

FIG. 5 is a plan view illustrating an auxiliary electrode according to one embodiment.

Referring to FIG. 5, the first auxiliary electrode SE1 may be arranged in a mesh shape in the display area DA. For example, the first auxiliary electrode SE1 may be disposed in a non-emitting area.

The second auxiliary electrode SE2 may be disposed in the first common voltage supply area CVA1 and/or the second common voltage supply area CVA2.

Even if the second auxiliary electrode SE2 and the first auxiliary electrode SE1 are not directly connected, the second auxiliary electrode SE2 and the first auxiliary electrode SE1 may be electrically connected to each other as the second auxiliary electrode SE2 and the first auxiliary electrode SE1 are in direct contact with a same common electrode CE.

As shown in FIG. 5, the second auxiliary electrode SE2 may be formed of one electrode covering the common electrode disposed in the first common voltage supply area CVA1 and/or the second common voltage supply area CVA2, but the disclosure is not limited thereto, and the second auxiliary electrode SE2 may be formed as multiple separate electrodes.

The third auxiliary electrode SE3 may be disposed in the first pad area PDA1 and the second pad area PDA2. Since the dummy electrode DE with which the third auxiliary electrode SE3 is in contact is electrically insulated from the common electrode CE, the third auxiliary electrode SE3 may be not electrically connected to the second auxiliary electrode SE2 and the first auxiliary electrode SE1.

As shown in FIG. 5, the third auxiliary electrode SE3 may be formed as one electrode covering the common electrode disposed in the first pad area PDA1 and the second pad area PDA2, but the disclosure is not limited thereto, and the third auxiliary electrode SE3 may be formed as multiple separate electrodes.

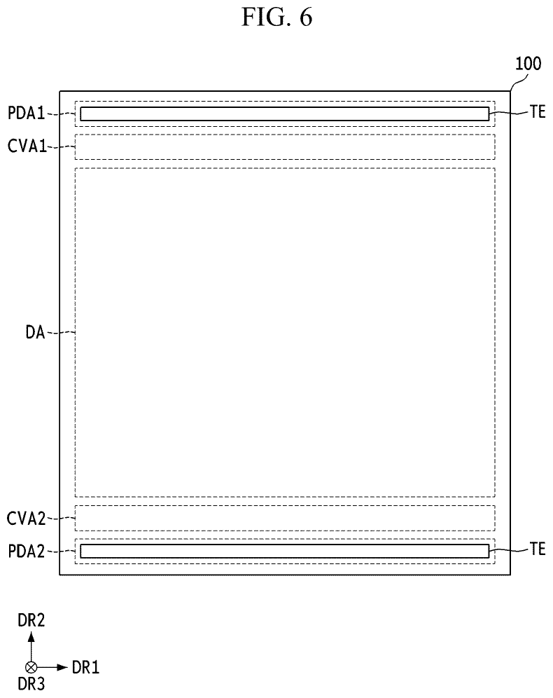

FIG. 6 is a plan view illustrating a transparent conductive layer according to one embodiment.

Referring to FIG. 6, the transparent conductive layer TE may be disposed in the first pad area PDA1 and the second pad area PDA2. Referring to FIGS. 5 and 6, the transparent conductive layer TE may overlap the third auxiliary electrode SE in a plan view. The transparent conductive layer TE may contact (e.g., directly contact) the third auxiliary electrode SE. The transparent conductive layer TE may be formed as one electrode covering the third auxiliary electrode SE3 disposed in the first pad area PDA1 and the second pad area PDA2.

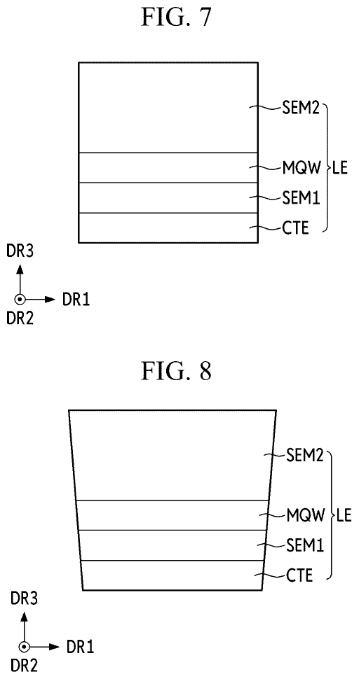

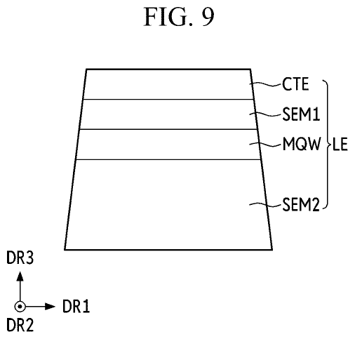

FIG. 7 is a schematic cross-sectional view illustrating a light emitting element LE according to one embodiment. FIG. 8 is a schematic cross-sectional view illustrating a light emitting element LE according to one embodiment. FIG. 9 is a schematic cross-sectional view illustrating a light emitting element LE according to one embodiment. For example, FIG. 8 schematically illustrates an embodiment that is different from the embodiment of FIG. 7 with respect to the shape of the light emitting element LE, and FIG. 9 schematically illustrates an embodiment that is different from the embodiment of FIG. 8 with respect to the arrangement direction of the light emitting element LE.

Referring to FIGS. 7 to 9, the light emitting element LE may include a first semiconductor layer SEM1, an active layer MQW, and a second semiconductor layer SEM2 sequentially arranged and/or stacked in the third direction DR3. In one embodiment, the light emitting element LE may further include a contact electrode CTE provided at an end. For example, the light emitting element LE may further include a contact electrode CTE provided at an end where the first semiconductor layer SEM1 is located.

The light emitting element LE may further include additional layers depending on embodiments. For example, the light emitting element LE may further include an electron blocking layer disposed between the first semiconductor layer SEM1 and the active layer MQW, and/or a superlattice layer disposed between the active layer MQW and the second semiconductor layer SEM2.

In one embodiment, the light emitting element LE may be an inorganic light emitting element made of an inorganic material. For example, the light emitting element LE may be an inorganic light emitting diode formed from a nitride-based semiconductor material such as GaN, AlGaN, InGaN, AlInGaN, AlN or InN, a phosphide-based semiconductor material such as GaP, GaInP, AlGaP, AlGaInP, AlP or InP, or any other inorganic material.

The contact electrode CTE may be provided and/or formed at an end of the light emitting element LE where the first semiconductor layer SEM1 is disposed. For example, the contact electrode CTE may be provided and/or formed on a surface of the first semiconductor layer SEM1. The contact electrode CTE may be an electrode that protects the first semiconductor layer SEM1 and readily connects the first semiconductor layer SEM1 to at least one circuit element, electrode, wiring, and/or conductive layer. The contact electrode CTE may include a metal, metal oxide, or other conductive material.

The first semiconductor layer SEM1 may be disposed on the contact electrode CTE. In one embodiment, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SEM1 may include other materials.

The first semiconductor layer SEM1 may include a semiconductor material doped with a first conductivity type dopant. For example, the first semiconductor layer SEM1 may include GaN (e.g., p-type dopant) doped with a first conductive dopant (e.g., p-type dopant) such as Mg, Zn, Ca, Se, Ba, or the like.

The active layer MQW may be disposed on the first semiconductor layer SEM1. The active layer MQW may emit light by recombination of electron-hole pairs according to an electrical signal applied through the first semiconductor layer SEM1 and the second semiconductor layer SEM2. For example, the active layer MQW may be a light emitting layer of the light emitting element LE.

The active layer MQW may include a material with a single or multiple quantum well structure. In case that the active layer MQW includes a material with a multi-quantum well structure, the active layer MQW may have a structure in which multiple well layers and barrier layers are alternately stacked each other. The active layer MQW may include three to five different semiconductor materials, depending on the wavelength band of the light emitted.

In one embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, the well layer may be formed of InGaN, and the barrier layer may be formed of GaN or AlGaN, but the disclosure is not limited thereto. In case that the active layer MQW includes InGaN, the color of light emitted from the light emitting element LE may be controlled by adjusting an amount of indium (In). The active layer MQW may also include other materials.

In one embodiment, the active layers MQW of the first light emitting element LE1, the second light emitting element LE2, and the third light emitting element LE3 shown in FIGS. 2 and 3 may emit light of a same color (e.g., blue light) as each other. In another embodiment, the active layers MQW of the first light emitting element LE1, the second light emitting element LE2, and the third light emitting element LE3 may emit light of different colors (e.g., red light, green light, and blue light, respectively).

The second semiconductor layer SEM2 may be disposed on the active layer MQW. In one embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SEM2 may also include other materials.

The second semiconductor layer SEM2 may include a semiconductor material doped with a second conductivity type dopant. For example, the second semiconductor layer SEM2 may include GaN (e.g., n-GaN) doped with a second conductive dopant (e.g., n-type dopant), such as Si, Ge, Sn, or the like.

In one embodiment, the first semiconductor layer SEM1 and the second semiconductor layer SEM2 may have different thicknesses in a thickness direction of the light emitting element LE (e.g., the third direction DR3). For example, the second semiconductor layer SEM2 may have a thickness greater than the first semiconductor layer SEM1 in the thickness direction of the light emitting element LE. Accordingly, the active layer MQW may be located closer to a first end (for example, a p-type end) of the light emitting element LE provided with the first semiconductor layer SEM1 than to a second end (for example, an n-type end) of the light emitting element LE provided with the second semiconductor layer SEM2.

In one embodiment, the light emitting element LE may be a vertical micro-LED extending and/or stacked in the third direction DR3. For example, the light emitting element LE may be a micro-LED having a length in the first direction DR1, a length in the second direction DR2, and a length in the third direction DR3 of tens to hundreds of micrometers (μm). In one embodiment, the length of the light emitting element LE in the first direction DR1, the length in the second direction DR2, and the length in the third direction DR3 may each be less than or equal to approximately 100 μm.

In one embodiment, the light emitting element LE may include a substantially vertical side surface as shown in FIG. 7. For example, the light emitting element LE may be patterned by vertical etching and may have a rectangular or square cross-sectional shape where the width of the top surface and the width of the lower surface are substantially equal.

The shape of the light emitting element LE may be varied in different embodiments. For example, the light emitting element LE may have a cross-sectional shape in which the width of the top surface and the width of the lower surface are different from each other.

In one embodiment, the light emitting element LE may have an inverted tapered cross-sectional shape as shown in FIG. 7. For example, the light emitting element LE may have an inverted trapezoidal cross-sectional shape in which the width of the top surface is greater than the width of the lower surface.

In one embodiment, the light emitting element LE may be disposed on the backplane substrate 110 such that the first semiconductor layer SEM1 is located below the active layer MQW and the second semiconductor layer SEM2 is located above the active layer MQW, as shown in FIG. 7. For example, the light emitting element LE may have a contact electrode CTE (or first semiconductor layer SEM1) in contact with the bonding electrode BOE of FIG. 3, the second semiconductor layer SEM2 (or another contact electrode or undoped semiconductor layer provided on the second semiconductor layer SEM2) may be disposed in each light emitting area EA to contact the common electrode CE, and the common electrode CE may be a cathode electrode.

In one embodiment, the light emitting element LE may be disposed on the backplane substrate 110 such that the second semiconductor layer SEM2 is located below the active layer MQW and the first semiconductor layer SEM1 is located above the active layer MQW, as shown in FIG. 9. For example, the light emitting element LE may be disposed in a respective light emitting area EA such that the second semiconductor layer SEM2 (or other contact electrodes provided on the second semiconductor layer SEM2) is in contact with the bonding electrode BOE of FIG. 3, the contact electrode CTE (or the first semiconductor layer SEM1) is in contact with the common electrode CME, and the common electrode CME may be an anode electrode.

In one embodiment, the light emitting element LE may have a regular taper cross-sectional shape as shown in FIG. 9. For example, the light emitting element LE may have a trapezoidal cross-sectional shape where the width of the top surface is smaller than the width of the bottom surface.

In one embodiment, the direction in which each wafer for forming the light emitting element LE is transferred to the carrier substrate may be adjusted to adjust the direction of the light emitting element LE disposed on the bonding electrode BOE. For example, the surface on which the bonding material is to be formed may be selected through the process of transferring the wafer to the carrier substrate once or twice or more.

The structure, material, size, and/or shape of the light emitting element LE are not limited to the above-described embodiments. For example, the structure, material, size, and/or shape of the light emitting element LE may vary depending on the embodiments.

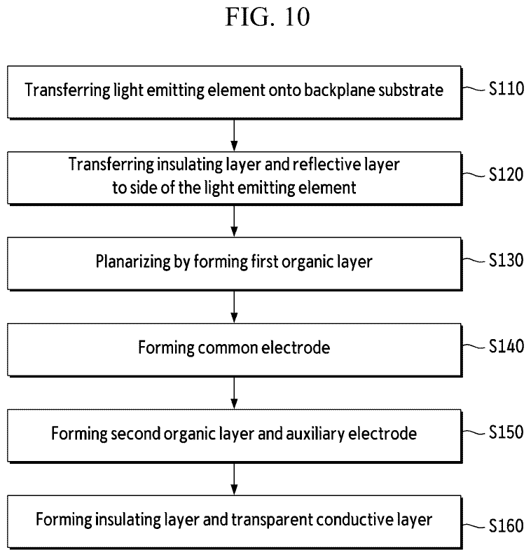

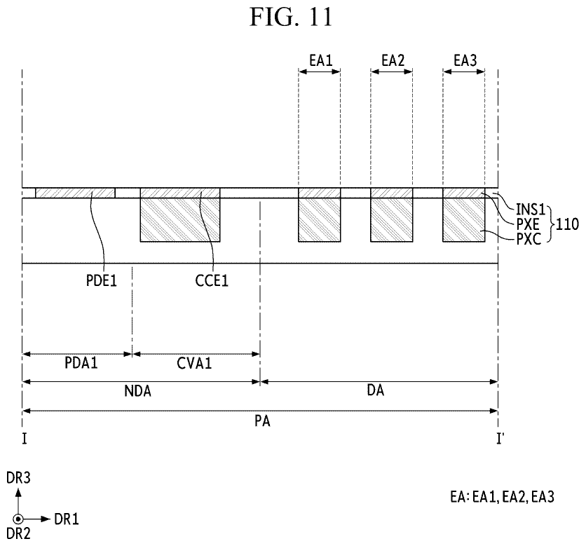

FIG. 10 is a flowchart describing a manufacturing method of a display device 10 according to one embodiment. FIGS. 11 to 21 are schematic cross-sectional views illustrating a manufacturing method of a display panel 100 according to one embodiment. For example, FIGS. 11 to 21 each schematically illustrate specific steps for forming the display panel 100 in the form of a cross-sectional view.

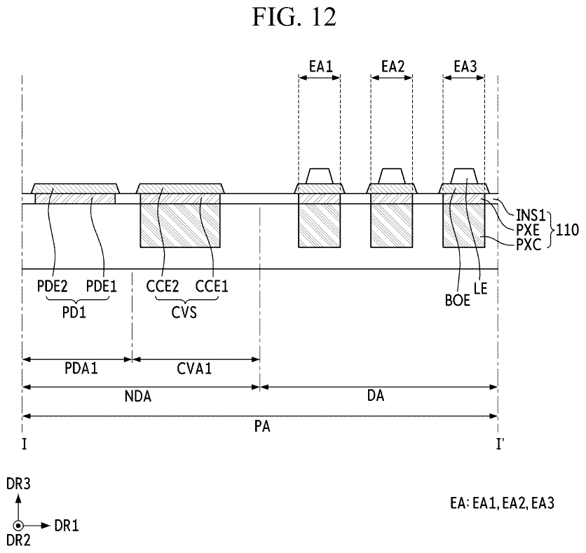

Referring to FIGS. 11 and 12, the light emitting element LE may be transferred onto the pixel electrodes PXE of the backplane substrate 110. (S110 in FIG. 10)

For example, a backplane substrate 110 may be prepared as shown in FIG. 11.

The backplane substrate 110 may include pixel electrodes PXE provided in each of the light emitting areas EA located in the display areas DA. For example, the backplane substrate 110 may include pixel electrodes PXE individually provided in each of the light emitting areas EA of panel area PA, pixel circuits PXC connected to a corresponding pixel electrode PXE, and a first insulating layer INS1 disposed around the pixel electrodes PXE. Further, the non-display area NDA of the backplane substrate 110 may include a first pad electrode PDE1 and a first common connection electrode CCE1, and a first insulating layer INS1 disposed around the first pad PD1 and the first common connection electrode CCE1. In one embodiment, the first pad electrode PDE1 and the first common connection electrode CCE1 of the non-display area NDA and the pixel electrodes PXE of the display area DA may be disposed on a same plane.

As shown in FIG. 12, a bonding material may be applied on the backplane substrate 110.

For example, a first conductive bonding layer may be formed on the first common connection electrode CCE1, the first pad electrode PDE1, and the pixel electrodes PXE by entirely applying a conductive bonding material on the top surface of the backplane substrate 110. For example, the first conductive bonding layer may be formed by applying (e.g., depositing) an all-over coating of gold (Au), copper (Cu), aluminum (Al), tin (Sn), or other bonding metal on the top surface of the backplane substrate 110. The first conductive bonding layer formed on the first common connection electrode CCE1 may form the second common connection electrode CCE2, and the first conductive bonding layer formed on the first pad electrode PDE1 may form the second pad electrode PDE2.

A second conductive bonding layer may be formed on a surface of the light emitting elements LE disposed on the transfer substrate.

The transfer substrate may be disposed on the backplane substrate 110, and the second conductive bonding layer of the light emitting element LE may be aligned on the first conductive bonding layer to bond the transfer substrate and the backplane substrate 110.

In one embodiment, the first conductive bonding layer of the backplane substrate 110 and the second conductive bonding layer of the transfer substrate may be melt-bonded through a bonding process of a backplane substrate 110 and a transfer substrate by a thermal compression (TC) bonding method. The first conductive bonding layer and the second conductive bonding layer may be melt-bonded at a temperature to form one conductive bonding layer BDL. For example, the conductive bonding layer BDL may be disposed between the backplane substrate 110 and the transfer substrate and serve as a bonding metal layer that bonds the backplane substrate 110 and the transfer substrate.

The bonding (or adhesion) method of the backplane substrate 110 and the transfer substrate is not limited thereto, and the backplane substrate 110 and the transfer substrate may be joined by other methods.

Thereafter, the transfer substrate may be removed from the light emitting elements LE.

For example, the transfer substrate may be separated using a laser lift off (LLO) process. The laser lift-off process may use a laser, and a KrF excimer laser (248 nm wavelength) may be used as the source. The energy density of the excimer laser may be irradiated in a range of about 550 mJ/cm² to about 950 mJ/cm², and the incident area may be in a range of about 50×50 μm² to about 1×1 cm², but the disclosure is not limited thereto. By irradiating the laser to the transfer substrate, the transfer substrate may be separated from the light emitting element LE.

In another embodiment, the transfer substrate may be readily and/or appropriately removed from epitaxial dies (EPD) through a polishing process such as a chemical mechanical polishing (CMP) process and/or an etching process.

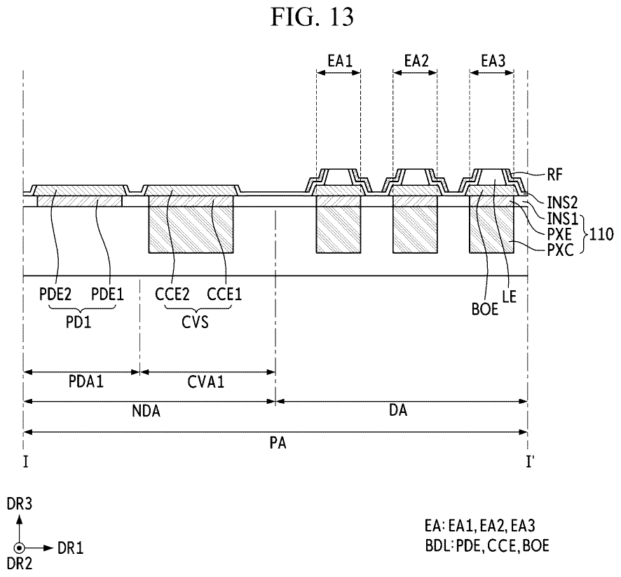

Referring to FIG. 13, a second insulating layer INS2 and a reflective layer RF may be transferred to the side of the light emitting element LE. (S120 in FIG. 10)

For example, an insulating material may be formed on the front surface of the backplane substrate 110. The insulating material layer may cover the light emitting elements LE, the first insulating layer INS1, the second common connection electrode CCE2, and the second pad electrode PDE2.

A partial etching may be performed to expose the top surface of the light emitting element LE, the second common connection electrode CCE2, and the second pad electrode PDE2.

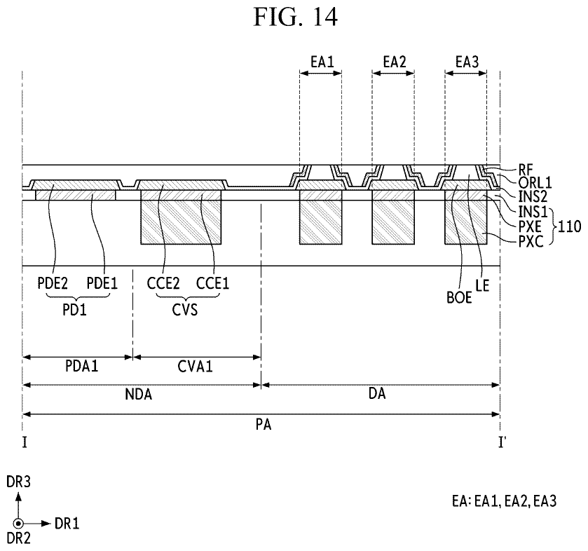

Referring to FIG. 14, a first organic layer ORL1 may be formed surrounding the light emitting elements LE and planarizing the light emitting elements LE. (S130 in FIG. 10)

For example, a filler may be applied to the backplane substrate 110 on which the light emitting elements LE are provided to fill the gaps between the light emitting elements LE and to flatten the top surface of the backplane substrate 110 on which the light emitting elements LE and the filler are provided. For example, an inorganic insulating material, such as silicon oxide (SiOₓ), silicon nitride (SiNₓ), silicon oxynitride (SiOₓN_{y}), aluminum oxide (AlₓO_{y}), aluminum nitride (AlN), or other insulating material, or the like, may be applied (e.g., deposited) on the top surface of the backplane substrate 110 to cover all of the light emitting elements LE.

In one embodiment, a planarization process may be performed by a polishing process such as a chemical mechanical polishing (CMP) process, but the method of planarizing the top surface of the backplane substrate 110 is not limited thereto. For example, the top surface of the backplane substrate 110 may be flattened through an etching process or the like.

After the process of planarizing the top surface of the backplane substrate 110, at least a portion of the top portion of the light emitting elements LE may be exposed. For example, the filler may remain on a side of the backplane substrate 110 in the form of filling the gap between the light emitting elements LE. The side surfaces of the light emitting elements LE may be surrounded by the filler. Therefore, the filler may serve as a protective layer that protects the light emitting elements LE.

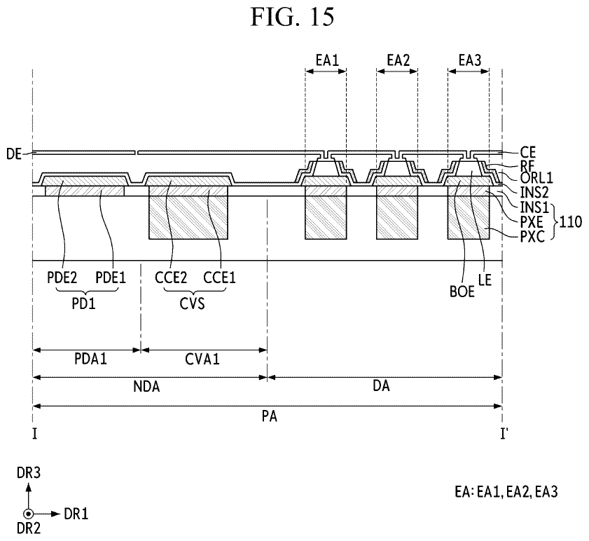

Referring to FIG. 15, a common electrode CE may be formed on the light emitting element LE and the first organic layer ORL1. (S140 in FIG. 10)

Referring to FIG. 15, a common electrode material layer may be formed in an entire area of the display area DA and the non-display area NDA. Thereafter, the space between the common electrode CE of the first pad area PDA1 and the common electrode CE of the first common voltage supply area CVA1 may be etched, and the common electrode CE of the first pad area PDA1 and the common electrode CE of the first common voltage supply area CVA1 may be separated. The common electrode CE of the first common voltage supply area CVA1 may form a dummy electrode DE.

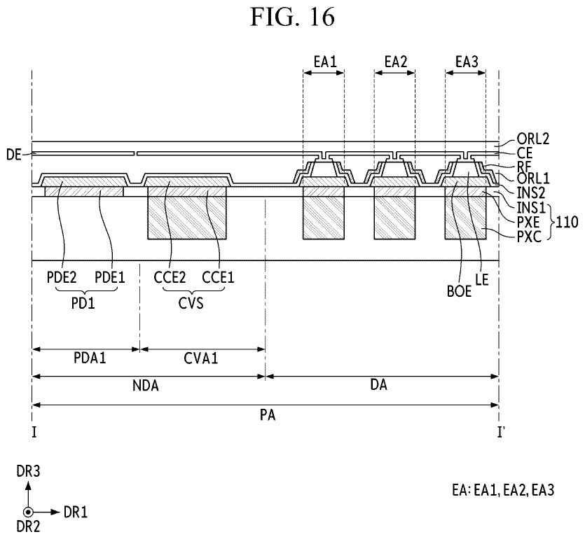

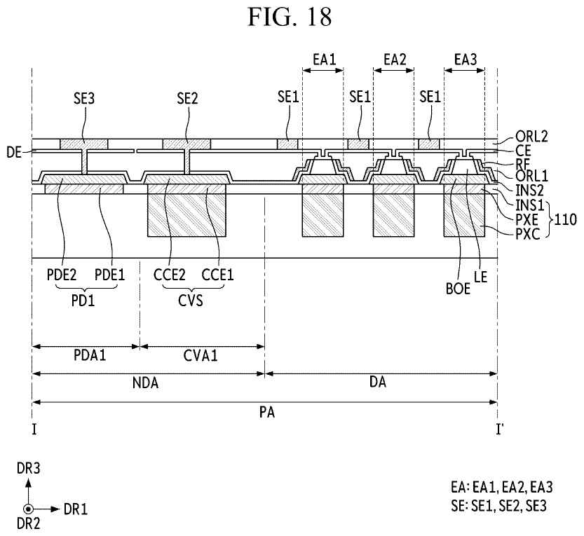

Referring to FIGS. 16 and 18, a second organic layer ORL2 and an auxiliary electrode SE may be formed. (S150 in FIG. 10)

Referring to FIG. 16, a second organic material layer may be applied on the backplane substrate 110 on which the common electrode CE is formed, and the top surface of the backplane substrate 110 may be planarized. For example, an inorganic insulating material, such as silicon oxide (SiOₓ), silicon nitride (SiNₓ), silicon oxynitride (SiOₓN_{y}), aluminum oxide (AlₓO_{y}), aluminum nitride (AlN), or other insulating material, or the like, may be applied (e.g., deposited) on the top surface of the backplane substrate 110 to cover both the common electrode CE and the dummy electrode DE.

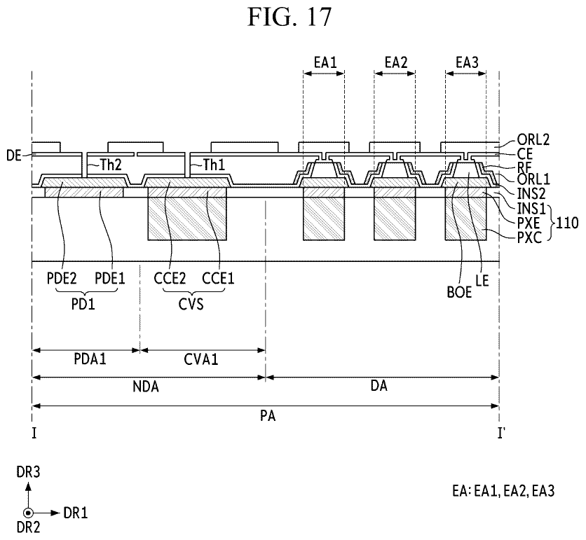

Referring to FIG. 17, a portion of the second organic layer ORL2 may be etched to expose a portion of the common electrode CE and the dummy electrode DE. For example, a portion of the second organic layer ORL2 in the non-emitting area of the display area DA may be etched, and the top of the second pad electrode PDE2 and the second common connection electrode CCE2 may be exposed.

Through holes Th1 and Th2 may be formed penetrating the common electrode CE and dummy electrode DE of the first pad area PDA1 and the common electrode connection portion CVS, the first organic layer ORL1, and the second insulating layer INS2.

Referring to FIG. 18, after forming an electrode material layer to completely cover the second organic layer ORL2, the top surface of the second organic layer ORL2 may be exposed through a planarization process.

Through this process, the first auxiliary electrode SE1 may be formed in the display area DA, the second auxiliary electrode SE2 may be formed in the first common voltage supply area CVA1, and the third auxiliary electrode SE3 may be formed in the first pad area PDA1. The second auxiliary electrode SE2 may be electrically connected to the second common connection electrode CCE2 through the first through hole Th1. The second auxiliary electrode SE2 may contact (e.g., directly contact) the common electrode CE. The second auxiliary electrode SE2 may be electrically connected to the common electrode CE. The third auxiliary electrode SE3 may be electrically connected to the second pad electrode PDE2 through the second through hole Th2. The third auxiliary electrode SE3 may contact (e.g., directly contact) the dummy electrode DE. The second auxiliary electrode SE2 may be electrically connected to the common electrode CE.

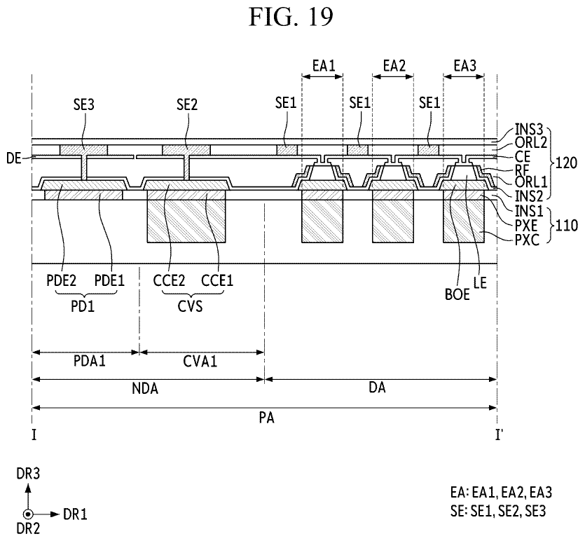

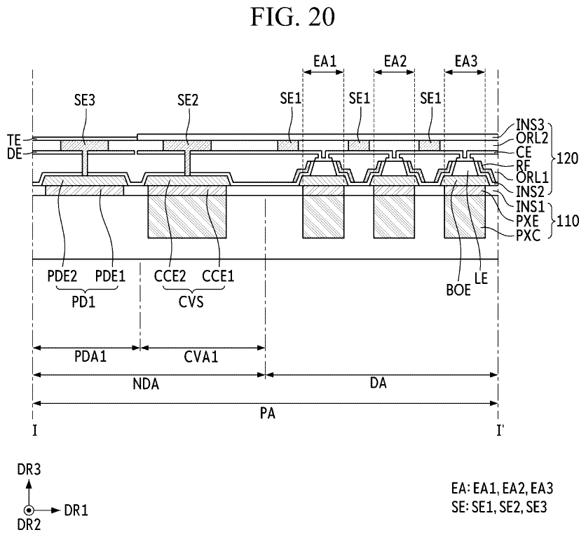

Referring to FIGS. 19 and 20, a third insulating layer INS3 and a transparent conductive layer TE may be formed. (S160 in FIG. 10)

Referring to FIG. 19, an insulating material layer may be applied to the entire display area DA and non-display area NDA. The insulating material layer in the first pad area PDA1 may be removed by etching. Accordingly, the third insulating layer INS3 may be formed on the second organic layer ORL2, the first auxiliary electrode SE1, and the second auxiliary electrode SE2 in the display area DA and the first common voltage supply area CVA1. A transparent conductive layer TE may be formed on the first pad area PDA1 where the third auxiliary electrode SE3 is exposed.

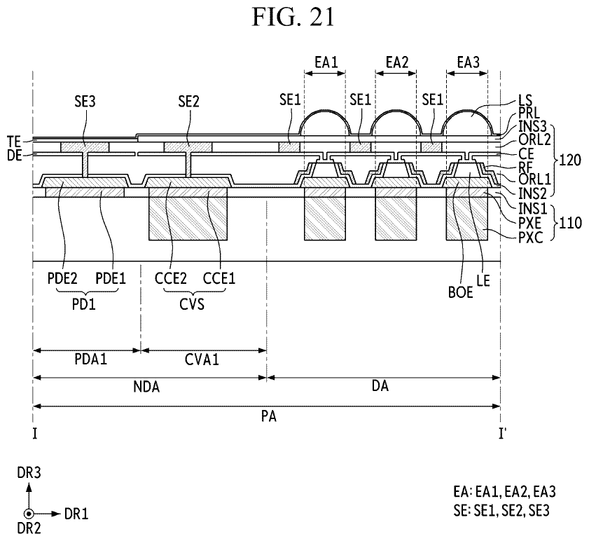

Referring to FIG. 21, for manufacturing the display panel 100 including a lens-type optical structure LS as shown in FIG. 3, a process of attaching and/or forming a lens-type optical structure LS and a protective layer PRL on the light emitting element layer 120 may be additionally performed.

Thereafter, the display device 10 including a display panel 100 may be manufactured by additionally performing a module process.

In the display panel 100 according to one embodiment, the dummy electrode DE, the third auxiliary electrode SE3, and the transparent conductive layer TE may overlap each other in the thickness direction in the first pad area PDA1. During the module process, the transparent conductive layer TE may protect the third auxiliary electrode SE3 from the outside. Also, even in case that the third auxiliary electrode SE3 is made of a material that diffuses readily, such as copper, diffusion onto the transparent conductive layer TE may be prevented.

The display device according to one embodiment of the present disclosure can be applied to various electronic devices. The electronic device according to the one embodiment of the present disclosure includes the display device described above, and may further include modules or devices having additional functions in addition to the display device.

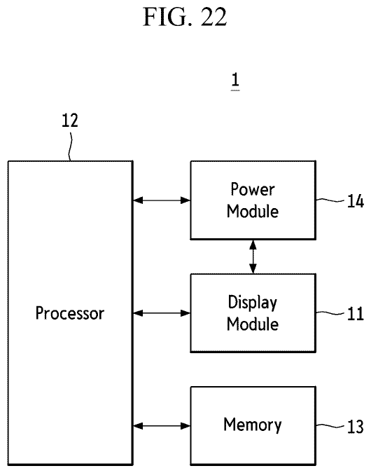

FIG. 22 is a block diagram of an electronic device according to one embodiment of the present disclosure.

Referring to FIG. 22, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

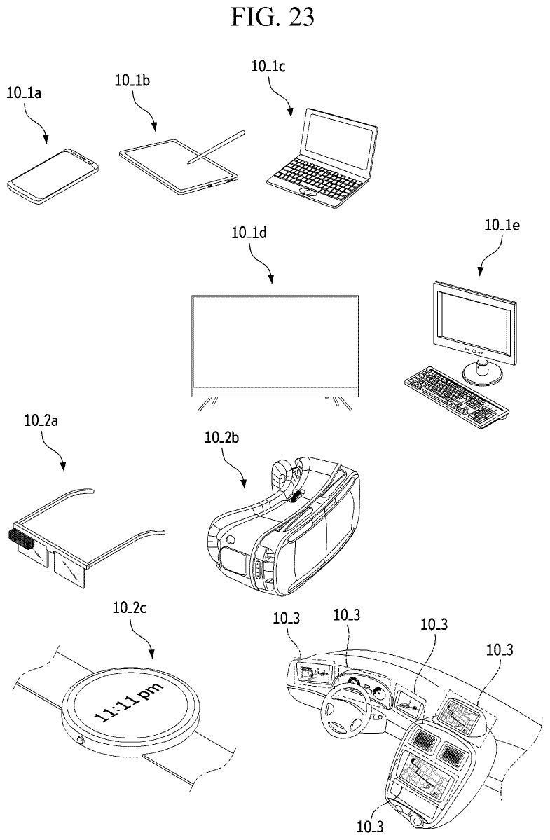

FIG. 23 is a schematic diagram of an electronic device according to various embodiments of the present disclosure.

Referring to FIG. 23, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a display area and a non-display area;
a plurality of pixel electrodes disposed on the substrate in the display area;
light emitting elements each disposed on a corresponding one of the plurality of pixel electrodes;
a common electrode disposed on the light emitting elements and commonly connected to a plurality of pixels; and
an auxiliary electrode disposed on the common electrode and not overlapping the light emitting elements in a thickness direction of the substrate.

2. The display device of claim 1, wherein the auxiliary electrode is made of a material having a resistance lower than a resistance of the common electrode.

3. The display device of claim 2, wherein the auxiliary electrode has a thickness smaller than a thickness of the common electrode.

4. The display device of claim 1, further comprising:
a micro lens overlapping the light emitting elements in the thickness direction.

5. The display device of claim 4, wherein the auxiliary electrode does not overlap the micro lens in the thickness direction.

6. The display device of claim 1, wherein the auxiliary electrode is electrically connected to the common electrode.

7. The display device of claim 1, wherein
the non-display area includes a common voltage supply area,
the display device further comprises a first common connection electrode disposed on the substrate in the common voltage supply area,
the common electrode extends from the display area to the common voltage supply area,
the auxiliary electrode includes a first auxiliary electrode disposed in the display area and a second auxiliary electrode disposed in the common voltage supply area, and
the second auxiliary electrode is electrically connected to the first common connection electrode by penetrating the common electrode.

8. The display device of claim 7, wherein the second auxiliary electrode is in contact with the common electrode and electrically connect the first common connection electrode and the common electrode.

9. The display device of claim 8, further comprising:
a bonding electrode disposed between the plurality of pixel electrodes and the light emitting elements; and
a second common connection electrode disposed on the first common connection electrode, wherein
the second common connection electrode and the bonding electrode are disposed on a same layer, and
the second auxiliary electrode is in contact with the second common connection electrode.

10. The display device of claim 7, wherein
the non-display area further includes a pad area,
the display device further comprises a pad electrode and a dummy electrode disposed in the pad area, the dummy electrode overlapping the pad electrode in the thickness direction, and
the dummy electrode and the common electrode are disposed on a same layer.

11. The display device of claim 10, wherein
the auxiliary electrode further includes a third auxiliary electrode disposed on the dummy electrode, and
the display device further comprises a transparent conductive layer disposed on the third auxiliary electrode.

12. The display device of claim 11, wherein the third auxiliary electrode is made of a material having a resistance lower than a resistance of the dummy electrode.

13. The display device of claim 11, wherein the third auxiliary electrode is in contact with the transparent conductive layer and the dummy electrode, and electrically connects the transparent conductive layer and the dummy electrode.

14. The display device of claim 11, wherein the transparent conductive layer comprises at least one of indium tin oxide (ITO), indium zinc oxide (IZO), and other transparent conductive material.

15. The display device of claim 10, further comprising:
a bonding electrode disposed between the plurality of pixel electrodes and the light emitting elements; and
a second common connection electrode disposed on the first common connection electrode, wherein
the second common connection electrode and the bonding electrode are disposed on a same layer, and,
the second auxiliary electrode is in contact with the second common connection electrode.

16. The display device of claim 1, further comprising:
an insulating layer surrounding a side of the light emitting elements; and
a reflective layer surrounding the side of the light emitting elements on the insulating layer.

17. A method of manufacturing a display device comprising:
transferring a plurality of light emitting elements to a substrate including a pixel electrode in a display area and a common connection electrode in a non-display area;
forming a first insulating layer and a reflective layer surrounding side surfaces of the plurality of light emitting elements;
forming an organic layer surrounding the plurality of light emitting elements and having a planar surface above the plurality of light emitting elements;
forming a common electrode on the plurality of light emitting elements and the organic layer; and
forming an auxiliary electrode on the common electrode not overlapping the plurality of light emitting elements in a thickness direction of the substrate.

18. The method of claim 17, wherein after the forming of the auxiliary electrode,
the auxiliary electrode is electrically connected to the common connection electrode by penetrating the organic layer in the non-display area.

19. The method of claim 18, wherein
the substrate further includes a pad electrode in the non-display area, and
the forming of the common electrode on the plurality of light emitting elements and the organic layer comprises:
forming an electrode material layer on the plurality of light emitting elements and the organic layer; and
forming a dummy electrode that overlaps the pad electrode in the thickness direction and the common electrode that overlaps the common connection electrode in the thickness direction by short-circuiting a portion of the electrode material layer that overlaps the pad electrode in the thickness direction and another portion of the electrode material layer that overlaps the common connection electrode in the thickness direction by an etching process.

20. The method of claim 19, further comprising:
forming a transparent conductive layer on the auxiliary electrode overlapping the dummy electrode in the thickness direction.

21. The method of claim 17, further comprising:
forming a lens-shaped optical structure on a light emitting element layer including the plurality of light emitting elements and the common electrode,
wherein the auxiliary electrode does not overlap the lens-shaped optical structure in the thickness direction.

22. An electronic device, comprising:
a display module that provides an image; and
a processor that transmits an image data signal to the display module,
wherein the display module comprises:
a substrate including a display area and a non-display area;
a plurality of pixel electrodes disposed on the substrate in the display area;
light emitting elements each disposed on a corresponding one of the plurality of pixel electrodes;
a common electrode disposed on the light emitting elements and commonly connected to a plurality of pixels; and
an auxiliary electrode disposed on the common electrode and not overlapping the light emitting elements in a thickness direction of the substrate.
